(19) United States
(12) Patent Application Publication
(10) Pub. No.: US 2008/0165483 A1
(43) Pub. Date: Jul. 10, 2008

(54) DISPLAY DEVICE

(76) Inventors: Yasuhiro Tanaka, Edogawa (JP); Hideo Kawakura, Chiba (JP); Hidenori Kikuchi, Chosei (JP); Satoshi Namiki, Isumi (JP); Masato Sawahata, Ichihara (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/965,819

(22) Filed: Dec. 28, 2007

(30) Foreign Application Priority Data
Dec. 28, 2006 (JP) 2006-353695

(51) Int. Cl. H05K 7/00

(52) U.S. Cl. 361/681

(57) ABSTRACT

The present invention provides a display device of high quality by suppressing heating of a semiconductor chip mounted on a flexible board connected to an insulation substrate of a display device and by suppressing irregularities of a voltage supplied to the semiconductor chip. A heat radiation pattern is formed on a flexible board which is connected to the insulation substrate of the display device and mounts a semiconductor chip thereon. By connecting heat radiation bumps of the semiconductor chip and the heat radiation pattern, heat generated from the semiconductor chip is dissipated by the heat radiation pattern. Further, by supplying a predetermined voltage to the semiconductor chip via the heat radiation pattern and the heat radiation bumps, the irregularities of an input voltage to the semiconductor chip can be also suppressed.

### CLAIM OF PRIORITY

The present application claims priority from Japanese application serial No. 2006-353695 filed on Dec. 28, 2006, the content of which is hereby incorporated by reference into this application.

### BACKGROUND OF THE INVENTION

1. Field of the Invention

The present invention relates to a display device, and more particularly to a technique which is effectively applicable to an organic EL (OLED) display device, a plasma display device, a field-effect-type display device (FED), not to mention a liquid crystal display device used in a mobile apparatus, a personal computer, a television receiver set or the like.

2. Description of Related Art

In a display device, the constitution which makes a pair of insulation substrates made of glass or the like face each other and forms pixels for a display between the pair of substrates has been popularly used. For example, in a transmissive liquid crystal display device used in a television receiver set or the like, liquid crystal is sealed between a pair of transparent substrates and the liquid crystal is driven by making use of an electric field generated between electrodes formed on one substrate or both substrates thus controlling optical transmissivity to perform a display.

In such a display device, lines for supplying a potential (or an electric current) to the above-mentioned electrodes are formed on the substrate. The lines are electrically connected to a drive circuit on an end portion of the substrate. As a mode for connecting the drive circuit to the substrate, there have been known several modes including a mode which directly adheres a semiconductor chip constituting a drive circuit to a substrate, a mode which connects a flexible board on which a semiconductor chip constituting a drive circuit is mounted to a substrate, and a mode which incorporates a function of a drive circuit in an external circuit and connects the external circuit and a substrate to with each other using a simple flexible printed circuit board.

Conventionally, as the flexible board where the semiconductor chip constituting the drive circuit is mounted, a TCP (Tape Carrier Package) which forms an opening in the flexible board and connects the semiconductor chip arranged in the opening portion and the lines formed on the flexible board using flying wires or the like has been mainly used. However, recently, a COF (Chip On Film) which mounts a semiconductor chip on a flexible board without forming an opening in a portion of the flexible board corresponding to the semiconductor chip, and connects lines formed on the flexible board and the semiconductor chip using an anisotropic conductive film or the like has been popularly used.

As patent documents related to the present invention, a patent document 1 (JP-A-2004-61892), a patent document 2 (JP-A-2004-240235) and a patent document 3 (JP-A-2002-278522) are named.

### SUMMARY OF THE INVENTION

The above-mentioned COF does not use the flying wires and hence, a line distance and a bump distance of the semiconductor chip can be narrowed compared to the conventional TCP. Accordingly, the COF can increase the line density compared to the TCP, can decrease the number of semiconductor chips used in a display device thus reducing the manufacturing cost of the display device.

However, along with the increase of integration of a semiconductor chip compared to the TCP, the COF increases a heat value of the semiconductor chip. Further, different from the TCP which forms the opening in the flexible board at the portion where the semiconductor chip is mounted, no opening is formed in the flexible board in COF and hence, it becomes necessary to cope with a task how to dissipate heat generated by the semiconductor chip. Further, along with the increase of integration of the semiconductor chip, there exists a tendency that an output voltage becomes unstable corresponding to a distance between power source bumps of the semiconductor chip and an output circuit.

Further, after connecting the bumps of the semiconductor chip and terminals of the flexible board, a resin is filled between the chip and the board for enhancing reliability. Here arises a drawback that an incomplete portion remains in resin sealing. For example, bubbles remains in the inside of the resin. Such a drawback may remarkably deteriorate a display performance of the display device.

Further, even when the COF is used, in the same manner as the conventional TCP, there still remains a drawback that it is necessary to form a capacitance element outside the semiconductor chip thus restricting the reduction of cost of the display device as a whole.

The present invention has been made to overcome the above-mentioned drawbacks and it is an object of the present invention to provide a technique which, in a COF which a display device includes, can suppress a phenomenon that a voltage of a semiconductor chip becomes unstable by efficiently dissipating the heat generated by the semiconductor chip and can fix the semiconductor chip and a flexible board to each other with high reliability.

The above-mentioned and other objects and the novel features of the present invention will become apparent from the description of this specification and attached drawings.

To briefly explain the summary of typical inventions among inventions disclosed in this specification, they areas follows.

To achieve the above-mentioned object, a display device of the present invention includes: an insulation substrate; a flexible board which is connected to the insulation substrate; and a semiconductor chip which is mounted on the flexible board, wherein the semiconductor chip includes a first long side and a second long side, first bumps are formed on the semiconductor chip along the first long side and second bumps are formed on the semiconductor chip along the second long side, the first bumps and the second bumps are connected to a plurality of lines formed on the flexible board, and a pattern formed of a metal layer formed on the same layer as the plurality of lines is formed on the flexible board between the first bumps and the second bumps.

Here, the pattern has a width larger than respective widths of the plurality of lines. Further, the pattern is formed on the flexible board in a state that the pattern extends from a portion of the flexible board where the semiconductor chip is mounted to a portion of the flexible board where the semiconductor chip is not mounted, and the pattern is formed between the flexible board and a protective film in the portion of the flexible board where the semiconductor chip is not mounted.

Further, the semiconductor chip includes a first short side and a second short side which are arranged orthogonal to the first long side, and the pattern is formed in a state that the pattern extends from a portion of the flexible board where the semiconductor chip is mounted to a portion of the flexible board where the semiconductor chip is not mounted between the first short side and the flexible board.

Further, third bumps are formed on the semiconductor chip between the first bumps and the second bumps, and the pattern and the third bumps are connected with each other. Here, a plurality of third bumps may be formed along the first long side. Further, an area of the third bump may be set larger than an area of the first bump and an area of the second bump.

Further, an opening is formed in a portion of a region of the flexible board where the pattern is formed. Still further, the opening formed in the flexible board may include an opening formed in a portion of the pattern. Here, the opening formed in the flexible board may be formed in a portion of the flexible board where the semiconductor chip is mounted, and the opening formed in the flexible board may be formed in a portion of the flexible board where the semiconductor chip is not mounted.

Further, the pattern includes a first pattern and a second pattern, and a capacitance is formed between the first pattern and the second pattern. Here, the first pattern is formed between the flexible board and the semiconductor chip, the second pattern is formed between the first pattern and the semiconductor chip, and an insulation layer is formed between the first pattern and the second pattern.

On the other hand, a back-surface pattern is formed on a surface of the flexible board opposite to a surface of the flexible board where the semiconductor chip is formed, the pattern is connected to some third bumps, and the back-surface pattern may be connected to some other third bumps which differ from some third bumps.

Besides the above-mentioned constitutions, the display device of the present invention includes an insulation substrate; a flexible board which is connected to the insulation substrate; and a semiconductor chip which is mounted on the flexible board, wherein the semiconductor chip includes a first long side and a second long side, first bumps are formed on the semiconductor chip along the first long side and second bumps are formed on the semiconductor chip along the second long side, a plurality of third bumps and a plurality of fourth bumps are formed between the first bumps and the second bumps, and a first pattern which is connected in common to the plurality of third bumps and a second pattern which is connected in common to the plurality of fourth bumps may be formed on the flexible board.

Here, the first pattern and the second pattern form a capacitance between the semiconductor chip and the flexible board. The first pattern may be formed between the semiconductor chip and the flexible board, and the second pattern may be formed between the first pattern and the semiconductor chip. The first pattern and the second pattern may form a capacitance on a portion of the flexible board where the semiconductor chip is not mounted.

Further, the first pattern and the second pattern may be formed in comb-teeth shape, and comb teeth of the respective patterns may be alternately formed so as to form the capacitance.

Here, a first voltage supplied to the semiconductor chip may be applied to the first pattern, and a second voltage supplied to the semiconductor chip may be applied to the second pattern.

To briefly explain advantageous effects acquired by the typical inventions among the inventions disclosed in the specification, they are as follows.

According to the display device of the present invention, in the COF which the display device includes, it is possible to suppress a phenomenon that a voltage of a semiconductor chip becomes unstable by efficiently dissipating heat generated by the semiconductor chip and, at the same time, it is possible to fix the semiconductor chip and a flexible board to each other with high reliability.

### BRIEF DESCRIPTION OF THE DRAWINGS

FIG. 1 is a plan view showing a drain driver of an embodiment of the present invention;

FIG. 2 is a block diagram showing the schematic constitution of a display device of the embodiment of the present invention;

FIG. 3 is a cross-sectional view of the drain driver shown in FIG. 1;

FIG. 4 is a plan view showing a drain driver of another embodiment of the present invention;

FIG. 5 is a plan view showing a drain driver of another embodiment of the present invention;

FIG. 6 is a cross-sectional view of the drain driver shown in FIG. 5;

FIG. 7 is a plan view showing a drain driver of another embodiment of the present invention;

FIG. 8 is a cross-sectional view of the drain driver shown in FIG. 7;

FIG. 9 is a plan view showing a drain driver of another embodiment of the present invention;

FIG. 10 is a cross-sectional view of the drain driver shown in FIG. 9;

FIG. 11 is a plan view showing a drain driver of another embodiment of the present invention;

FIG. 12 is a plan view showing a drain driver of another embodiment of the present invention;

FIG. 13 is a plan view showing a drain driver of another embodiment of the present invention;

FIG. 14 is a cross-sectional view of the drain driver shown in FIG. 13;

FIG. 15 is a plan view showing a drain driver of another embodiment of the present invention;

FIG. 16 is a plan view showing a drain driver of another embodiment of the present invention;

FIG. 17 is a plan view showing a drain driver of another embodiment of the present invention;

FIG. 18 is a plan view showing a drain driver of another embodiment of the present invention;

FIG. 19 is a plan view showing a drain driver of another embodiment of the present invention;

FIG. 20 is a plan view showing a drain driver of another embodiment of the present invention;

FIG. 21 is a plan view showing a drain driver of another embodiment of the present invention;

FIG. 22 is a view showing a capacitance of another embodiment of a capacitance shown in FIG. 21;

FIG. 23 is a plan view showing a drain driver of another embodiment of the present invention;

FIG. 24 is a plan view showing a drain driver of another embodiment of the present invention;

FIG. 25 is a cross-sectional view of the drain driver shown in FIG. 24;

FIG. 26 is a cross-sectional view showing another constitution of the drain driver shown in FIG. 24; and

FIG. 27 is a cross-sectional view showing another constitution of the drain driver shown in FIG. 24.

### DESCRIPTION OF THE PREFERRED EMBODIMENTS

Hereinafter, an embodiment of the present invention is explained in detail in conjunction with drawings.

Here, in all drawings for explaining the embodiment, parts having the identical functions are given same numerals and their repeated explanation is omitted.

### Embodiment

The present invention is a technique which is effectively applicable to, not to mention a liquid crystal display device, a display device such as an organic EL (OLED) display device, a plasma display device, a field-effect-type display device (FED) or the like.

Hereinafter, the constitution of the liquid crystal display device is explained. The liquid crystal display device is constituted of a liquid crystal display panel, a drive circuit, aback light, a casing and the like. The liquid crystal display panel is constituted of a TFT substrate on which TFTs (thin film transistors) are formed, a counter substrate which is arranged to face the TFT substrate in an opposed manner, and liquid crystal composition sealed between the TFT substrate and the counter substrate. The drive circuit includes gate drivers which supply scanning signals to gate lines which are formed on the TFT substrate, drain drivers which supply video signals to drain lines formed on the TFT substrate, a TFT control circuit (also referred to as T-CON) which supplies video data and timing signals to both drivers and the like.

FIG. 2 shows, among parts which constitute the liquid crystal display device, the TFT substrate (SUB1), gate drivers (GD), drain drivers (DD) and a printed circuit board (PCB) on which a TFT control circuit and the like are formed. In the actual liquid crystal display device, the above-mentioned other constitutional elements are necessary. However, the constitutional elements which are not directly relevant to the present invention are not shown in the drawing. The TFT substrate is constituted of an insulation substrate made of glass or plastic, lines such as gate lines, drain lines and the like which are formed on one surface of the insulation substrate, the TFTs and the like. Although there may be a case that the TFT substrate is referred to as a body which includes, besides the TFT substrate, optical parts such as a polarizer, a retardation plate and the like formed on another surface of the insulation substrate, the explanation of these parts is omitted in this specification. A plurality of gate lines (or scanning lines) (GL) is formed on the insulation substrate in parallel to each other, while a plurality of drain lines (or video lines) (DL) is formed on the insulation substrate in parallel to each other in the direction orthogonal to the gate lines. Although the numbers of the gate lines and the drain lines are determined corresponding to the resolution of the liquid crystal display device, only some gate lines and some drain lines are shown in FIG. 2. A pixel region (PX) is formed in a portion of the TFT substrate surrounded by two gate lines (GL) and two drain lines (DL). The pixel regions are arranged in a matrix array on the TFT substrate. The TFT is formed in each pixel region and has a gate electrode thereof connected to the gate line (including a case that the gate electrode is integrally formed with the gate line) and a drain electrode thereof connected to the drain line. Further, a source electrode of the TFTs is connected to a pixel electrode. The pixel electrode generates an electric field between the pixel electrode and a counter electrode formed on the counter substrate not shown in the drawing, and drives liquid crystal molecules in the liquid crystal composition existing in both electrodes thus controlling optical transmissivity to perform a display. Further, holding capacitance lines not shown in the drawing are formed on the insulation substrate, and holding capacitance is formed between the pixel electrode and the holding capacitance line.

In this specification, the TFTs are formed on the TFT substrate as switching elements. However, the switching elements formed on the TFT substrate are not particularly limited to the TFT and may be formed of a 2-terminal element such as a diode. Further, the pixel electrode is configured to generate the electric field between the pixel electrode and the counter electrode formed on the counter substrate. However, as in the case of a so-called in-plane method (IPS method), an electric field parallel to the TFT substrate may be generated between a counter electrode and the pixel electrode formed on the TFT substrate side, and liquid crystal molecules are driven by such a parallel electric field. Further, the pixel electrode is not limited to the constitution which forms the holding capacitance between the pixel electrode and the holding capacitance line, and may be configured to form the holding capacitance between the pixel electrode and the neighboring gate line. Further, on the TFT substrate, dummy drain lines, dummy gate lines, lines which prevent the electrostatic breakdown or the like may be formed. Further, in this specification, with respect to the electrodes of the thin film transistor, the electrode on the side which is connected to the pixel electrode is referred to as a source electrode. However, the relationship between the source electrode and the drain electrode may be reversed based on the bias relationship. It may be possible to refer the electrode connected to the pixel electrode as the drain electrode, the above-mentioned drain line as the source line, and the above-mentioned drain driver as the source driver.

The gate drivers (GD) connected to the gate lines and the drain drivers (DD) connected to the drain lines are arranged on peripheries of the TFT substrate. Further, the drain drivers are also connected to a printed circuit board (PCB) on which the TFT control circuit is mounted. The gate driver and the drain driver are respectively constituted of a flexible board such as a base film made of a resin, a line layer formed on the flexible board and a semiconductor chip mounted on the flexible board and connected to the line layer. The constitutions of the gate driver and the drain driver are explained in detail later. A power source voltage, display data, control signals and the like are inputted to the printed circuit board from the outside of the liquid crystal display device. On the printed circuit board, besides the TFT control circuit which supplies timing signals and the like to the gate drivers and the drain drivers, although not particularly limited, a power source circuit which generates gray-scale voltages and the like are mounted.

In FIG. 2, the printed circuit board is connected only to the drain drivers. The timing signals, the power source voltages, clocks and the like to the gate driver are supplied from the printed circuit board via the line layers in the drain drivers and the lines formed on the TFT substrate. Further, the transfer of the timing signals, the power source voltages, clocks and the like between the gate drivers is also performed via lines formed on the TFT substrate. However, the constitution for transferring the timing signals, the power source voltages, the clocks and the like is not limited to the above-mentioned constitution and may be constituted such that the gate drivers are also connected to the printed circuit board in the same manner as the drain drivers. Further, it may be possible to adopt a method which connects the printed circuit board only to the gate driver and supplies the video data, the timing signals and the like supplied to the drain driver via the lines of the gate driver and the lines formed on the TFT substrate. Further, some functions of the power source circuit and the TFT control circuit formed on the printed circuit board may be imparted to the inside of the drain driver, the inside of the gate driver or the TFT substrate. Here, although the naming of the drain driver and the gate driver may be used to refer to only the semiconductor chip mounted on the flexible board, in this specification, the whole body including the semiconductor chip and the flexible board where the semiconductor chip is mounted is referred to as the drain driver and the gate driver respectively.

The above-mentioned constitution is explained in detail with respect to the liquid crystal display device. However, the above-mentioned constitution formed of the TFT substrate, the drain driver and the gate driver can be also used in the organic EL (OLED) display device and hence, the present invention is applicable to the organic EL display device. Further, the display device such as the plasma display device, the field-effect-type display device (FED) or the like does not use the TFT substrate. However, provided that the display device forms pixel regions on an insulation substrate and forms drive circuits which correspond to the above-mentioned drain drivers and gate drivers on a periphery of the insulation substrate, the present invention is applicable to the display device.

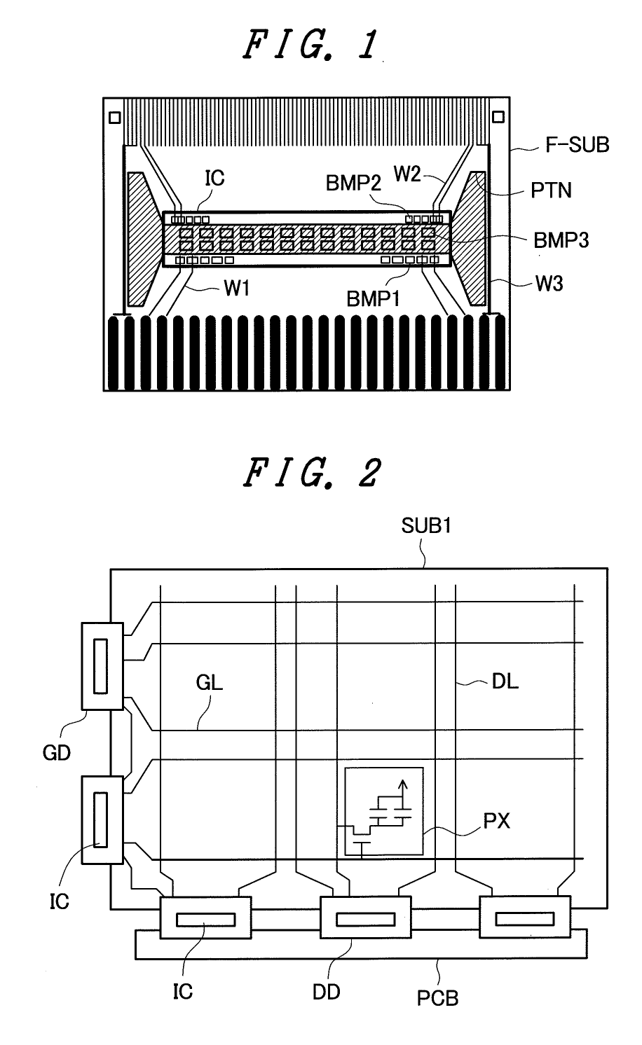

FIG. 1 is a view showing the detail of the drain driver (DD) shown in FIG. 2. An upper side of the drain driver (DD) in the drawing is connected to the TFT substrate, and a lower side of the drain driver (DD) in the drawing is connected to the printed circuit board. In the drain driver, a semiconductor chip (IC) is mounted on the flexible board (F-SUB) made of a resin. Further, on the flexible board, first lines (W1) for electrically connecting input bumps (BMPL) of the semiconductor chip and terminals of the printed circuit board and second lines (W2) for electrically connecting output bumps (BMP2) of the semiconductor chip and terminals formed on the TFT substrate are formed. Here, on end portions of the first lines, terminal portions which are connected with terminals of the bumps of the semiconductor chip and terminals of the printed circuit board are formed. Unless otherwise specified, in this specification, these terminal portions are also considered as parts of the first lines and are included in the first lines. In the same manner, the second lines also include the terminal portions which are connected to the bumps of the semiconductor chip and the terminals of the TFT substrate.

In FIG. 1, the input bumps and the output bumps are formed along the respective sides of the opposing long sides of the semiconductor chips, and a heat radiation pattern (PTN) is formed between the input bumps and the output bumps.

The heat radiation pattern is provided for dissipating heat which the semiconductor chip generates and a portion of the heat radiation pattern is provided between the flexible board and the semiconductor chip. Further, the heat radiation pattern is formed of the same material as the first line and the second line formed on the flexible board. In forming the first lines and the second lines by etching a metal layer made of copper or the like which is formed on a whole surface of the flexible board, the heat radiation pattern is formed along with the formation of the first lines and the second lines. That is, the heat radiation pattern has no place where the heat radiation pattern overlaps the first lines, the second lines and third lines (W3) described later. In other words, in a state before the semiconductor chip is mounted on the flexible board, the heat radiation pattern is electrically insulated from the first lines, the second lines and the third lines. Further, a width of the heat radiation pattern is set larger than widths of the first line, the second line and the third line. Further, the heat radiation pattern is formed on the flexible board in a state that the heat radiation pattern extends from a portion of the flexible board where the semiconductor chip is mounted to a portion of the flexible board where the semiconductor chip is not mounted. That is, the heat radiation pattern formed between the semiconductor chip and the flexible board extends to the outside of the semiconductor chip by striding over two opposing short-side portions of the semiconductor chip. In this manner, by extending the heat radiation pattern astride two short-side portions of the semiconductor chip, it is possible to increase the heat radiation efficiency. However, even when the heat radiation pattern strides over either one of the short-side portions or even when the heat radiation pattern is formed only between the semiconductor chip and the flexible board without striding over the short-sides, it is possible to acquire the heat radiation effect.

Further, on the flexible board, the third lines (W3) are formed as lines which are not connected with the semiconductor chip. The third lines are lines which directly connect with the printed circuit board and the TFT substrate. The third lines are provided for supplying predetermined potentials to the counter electrodes, the holding capacitance lines or lines for preventing electrostatic breakdown or for supplying timing signals, the power source voltage, clocks or the like to the gate drivers. The third lines are formed on the flexible board at positions remote from the semiconductor chip. The heat radiation pattern extends from the short-side portion of the semiconductor chip to a position in the vicinity of the third line. In FIG. 1, one third line is provided at the respective left and right sides of the drain driver. However, the number of the third lines is not limited to one and the third lines may be formed in plural. Further, although the third line is formed of a bold line compared to the first line and the second line, a diameter of the third line is not particularly limited.

Further, in FIG. 1, a plurality of third bumps (BMP3) to be connected to the heat radiation pattern is formed between the input bumps and the output bumps formed along the respective opposing long sides of the semiconductor chip. The plurality of third bumps is arranged in plural rows parallel to the long sides of the semiconductor chip. In this embodiment, a unit area (an area per one bump) of the third bumps for heat radiation is set larger than unit areas of the input bumps and the output bumps. Accordingly, it is possible to efficiently transfer the heat from the semiconductor chip to the heat radiation pattern. On the other hand, it is also possible to set the unit area of the third bumps for heat radiation equal to the unit areas of the input bumps and the output bumps. Due to such a constitution, it is unnecessary to form the bumps having different sizes and hence, the manufacture of the semiconductor chips is facilitated. Further, in FIG. 1, the third bumps are arranged in two rows along the opposing long sides of the semiconductor chip. However, the arrangement of the third bumps is not limited to such an arrangement. For example, bumps having a size larger than the size of the third bumps shown in FIG. 1 may be formed only in one row. Further, even when the third bumps may be arranged in plural rows, for example, the unit area of the third bumps on a side close to the output bumps and the unit area of the third bumps on a side close to the input bumps may be set different from each other. That is, there exists tendency that the closer the third bumps to the output bumps, the higher an internal voltage of the semiconductor chips becomes so that a heat value generated by a circuit such as an output amplifier is increased. Accordingly, to efficiently dissipate heat generated by the semiconductor chip, the unit area of the third bumps on a side closer to the output bumps may be set larger than the unit area of the third bumps on a side closer to the input bumps. It is needless to say that without setting the unit area of the third bumps different from each other on the output bump side and the input bumps side, the formation density of the third bumps may be set different from each other between the output bump side and the input bump side. Further, the unit area of the third bumps at a center portion in the longitudinal direction and the unit area of the third bumps on end-portion sides in the longitudinal direction (opposing short sides of the semiconductor chip) may be set different from each other. That is, by taking a state that it is difficult to dissipate heat at the center portion in the longitudinal direction into consideration, the unit area of the third bumps at the center portion in the longitudinal direction may be set larger than the unit area of the third bumps on the end-portion sides in the longitudinal direction. It is needless to say that, also in this case, without setting the unit area of the third bumps at the center portion in the longitudinal direction and the unit area of the third bumps on the end-portion side in the longitudinal direction different from each other, the arrangement density of the third bumps may be set different from each other. Here, the heat radiation pattern of this embodiment is configured to cover a main surface of the semiconductor chip and hence, the present invention can also acquire a shielding effect. Further, the predetermined input bumps and the third bumps may be electrically connected with each other via a line layer formed on the semiconductor chip so as to supply predetermined potentials to the heat radiation pattern.

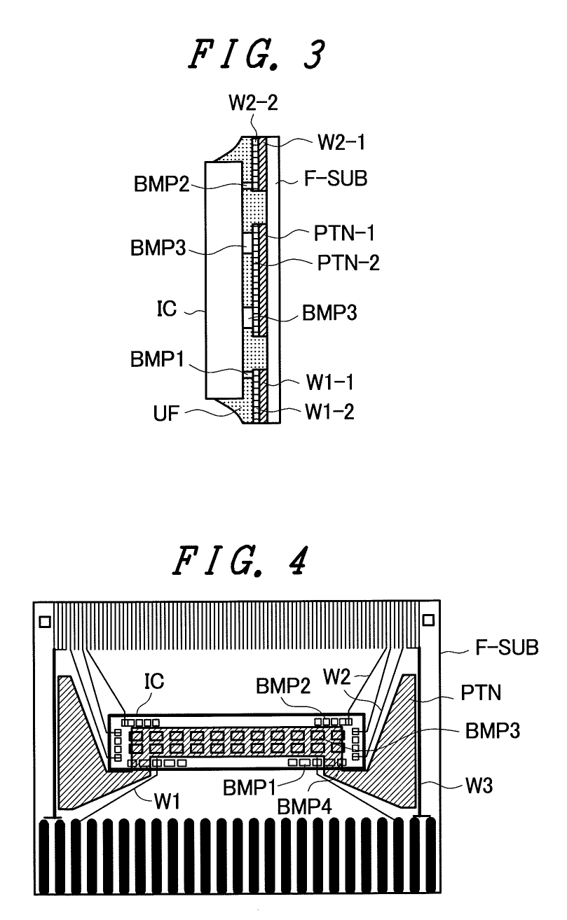

FIG. 3 is a cross-sectional view of the drain driver shown in FIG. 1. On the flexible board (F-SUB), the first lines which are connected to the input bumps (BMP1) of the semiconductor chip (IC) and the second lines which are connected to the output bumps (BMP2) of the semiconductor chip are mounted. Further, the heat radiation pattern is formed between the first lines and the second lines. The first lines, the second lines and the heat radiation pattern are respectively formed of a metal layer (W1-1, W2-1, PTN-1) made of a copper foil or the like formed on the flexible board and a plating layer (W1-2, W2-2, PTN-2) formed on the metal layer. The first lines, the second lines and the heat radiation pattern are formed, in general, by a method which forms a metal layer and a plating layer on a whole surface of the flexible board and performs patterning by etching the metal layer and the plating layer. However, the forming method is not limited to such a method, and the first lines, the second lines and the heat radiation pattern may be formed by other method such as printing. The first lines, the second lines and the heat radiation pattern are connected to the input bumps (BMP1), the output bumps (BMP2) and the third bumps (BMP3) of the semiconductor chip respectively. Further, to block connecting portion between the respective bumps and the lines and the connecting portion between the respective bumps and the heat radiation pattern from the outside air, an underfill (UF) made of a resin is filled between the semiconductor chip and the flexible board as a protective film. In the TCP (Tape Carrier Package) described in the Description of the Related Art, the opening is formed in the portion of the flexible board where the semiconductor chip is mounted. However, in a COF of the present invention, an opening is not formed in a portion of the flexible board where the semiconductor chip is mounted. Accordingly, the underfill is filled between the semiconductor chip and the flexible board from a side on which the semiconductor chip is formed.

Here, in FIG. 3, a flexible-board-side surface of the semiconductor chip and the flexible board are shown parallel to each other. However, depending on flatness of a surface of a bonding tool in mounting the semiconductor chip on the flexible board, there arises a case in which the flexible-board-side surface of semiconductor chip and the flexible board are not parallel to each other. Accordingly, a height of the input bumps, a height of the output bumps and a height of the third bumps may be set different from each other. Further, in place of setting the heights of these bumps per se different from each other, the heights of distal ends of the bumps may be set different from each other by making thicknesses of the insulation films or the line layers formed on the semiconductor chip formed below the bumps different from each other or by removing the insulation films or the line layers.

FIG. 4 is a view showing another drain driver. Also in FIG. 4, the upper side of the drain driver is connected to the TFT substrate and the lower side of the drain driver is connected to the printed circuit board. The drain driver shown in FIG. 4 is similar to the drain driver shown in FIG. 1 and hence, the explanation of the constitution of the drain driver in FIG. 4 which is already explained in conjunction with FIG. 1 is not repeated. Output bumps of a semiconductor chip which are formed on the drain driver in FIG. 4 are formed along one long side and two opposing short sides of the semiconductor chip. By obtaining a large number of outputs from one semiconductor chip, the number of drain drivers which are used in one liquid crystal display device can be decreased thus lowering a manufacturing cost of parts as a whole. The output bumps which are formed on three sides of the semiconductor chip are electrically connected to terminals on the TFT substrate via second lines formed corresponding to the output bumps. The output bumps are formed on three sides of the semiconductor chip and hence, input bumps of the semiconductor chip are formed along remaining one side of the semiconductor chip. Further, the heat radiation pattern (PTN) formed between the semiconductor chip and the flexible board is pulled out to a portion of the flexible board where the semiconductor chip is not formed from a portion of the side of the semiconductor chip on which the input bumps are formed. However, in the same manner as the drain driver shown in FIG. 1 also in the drain driver shown in FIG. 4, the heat radiation pattern which is formed between the semiconductor chip and the flexible board is pulled out to a portion of the flexible board where the semiconductor chip is not mounted through a gap formed between the output bumps and the input bumps, and the pull-out heat radiation pattern is formed in a region surrounded by the first lines, the second lines and the third lines.

Here, in FIG. 4, in the same manner as the constitution shown in FIG. 1, the heat radiation pattern is electrically connected to the third bumps of the semiconductor chip. Further, the heat radiation pattern shown in FIG. 4 is also electrically connected to fourth bumps (BMP4) formed in the same row as the input bumps. In FIG. 4, the fourth bumps have the same shape as the input bumps, and a pitch between the fourth bumps is also set equal to a pitch between the input bumps. However, an area of the input bump may be set different from an area of the fourth bump, and the pitch between the input bumps may be set different from the pitch between the fourth bumps. Further, predetermined input bumps and the fourth bumps may be electrically connected with each other by way of a line layer formed on the semiconductor chip so as to supply a predetermined potential to the heat radiation pattern. It is needless to say that the fourth bumps may not be formed. That is, the bumps may not be formed on a portion where the heat radiation pattern is pulled out to a portion of the flexible board where the semiconductor chip is not mounted through a gap formed between the semiconductor chip and the flexible board.

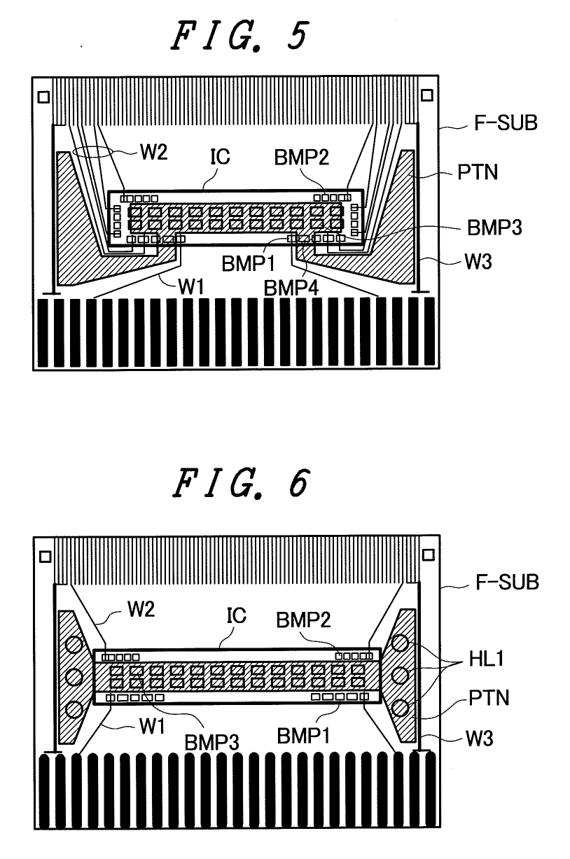

FIG. 5 is a view showing another drain driver. Also in FIG. 5, the upper side of the drain driver is connected to the TFT substrate and the lower side of the drain driver is connected to the printed circuit board. In the same manner as the constitution of the drain driver shown in FIG. 4, the explanation of the constitution of the drain driver in FIG. 5 which is already explained in conjunction with FIG. 1 is not repeated. The output bumps of the semiconductor chip mounted on the drain driver shown in FIG. 5 are formed along two opposing long sides and two opposing short sides of the semiconductor chip. Here, with respect to the long side on a side close to the printed circuit board (a lower side in the drawing), output bumps are formed on both ends of the long side, and input bumps are formed on a center portion of the long side (a portion sandwiched between the output bumps on both ends). Due to such a constitution, the drain driver shown in FIG. 5 can decrease a size of the semiconductor chip compared to the drain driver shown in FIG. 4, or when the semiconductor chip shown in FIG. 4 and the semiconductor chip shown in FIG. 5 have the same size, the number of output bumps can be increased. Accordingly, it is possible to further reduce a manufacturing cost of parts of the liquid crystal display device as a whole. The output bumps formed on four sides of the semiconductor chips are electrically connected to the terminals on the TFT substrate via the second lines formed corresponding to the output bumps. The heat radiation pattern (PTN) formed between the semiconductor chip and the flexible board is pulled out to a portion of the flexible board where the semiconductor chip is not mounted through gaps formed between the output bumps formed on both ends of the long side (lower side in the drawing) close to the printed circuit board and the input bumps arranged between the output bumps. Also in the drain driver shown in FIG. 5, the heat radiation pattern formed between the semiconductor chip and the flexible board is pulled out to a portion of the flexible board where the semiconductor chip is not mounted through a gap formed between the output bumps and the input bumps, and the pull-out heat radiation pattern is formed in a region surrounded by the first lines, the second lines and the third lines. Further, the heat radiation pattern shown in FIG. 5 is also electrically connected to the fourth bumps (BMP4) formed in the same row as the input bumps. In FIG. 5, the fourth bumps have the same shape as the input bumps, and the pitch between the fourth bumps is set equal to the pitch between the input bumps. However, the shape and the bump pitch of the fourth bump may be set different from the shape and the bump pitch of the input bumps. Further, in the same manner as the constitution shown in FIG. 4, predetermined input bumps may be electrically connected with the fourth bumps via the line layer formed on the semiconductor chip so as to supply a predetermined potential to the heat radiation pattern. It is needless to say that the fourth bump may have the same shape as the output bump, the pitch between the fourth bumps may be set equal to the pitch between the output bumps, or the fourth bumps may not be formed.

FIG. 6 is a view showing a drain driver of another embodiment of the present invention. Also in FIG. 6, an upper side of the drain driver is connected to the TFT substrate, while a lower side of the drain driver is connected to the printed circuit board. This embodiment is a modification of the embodiment shown in FIG. 1 and hence, the explanation of the constitution which is already explained in conjunction with the embodiment shown in FIG. 1 is not repeated. The drain driver shown in FIG. 6 is characterized in that openings (HL1) are formed in portions of the flexible board (F-SUB) where the heat radiation pattern (PTN) is formed. In this embodiment, three circular openings are formed in the left and right sides of the flexible board respectively. However, the shape and the number of the openings are not particularly limited.

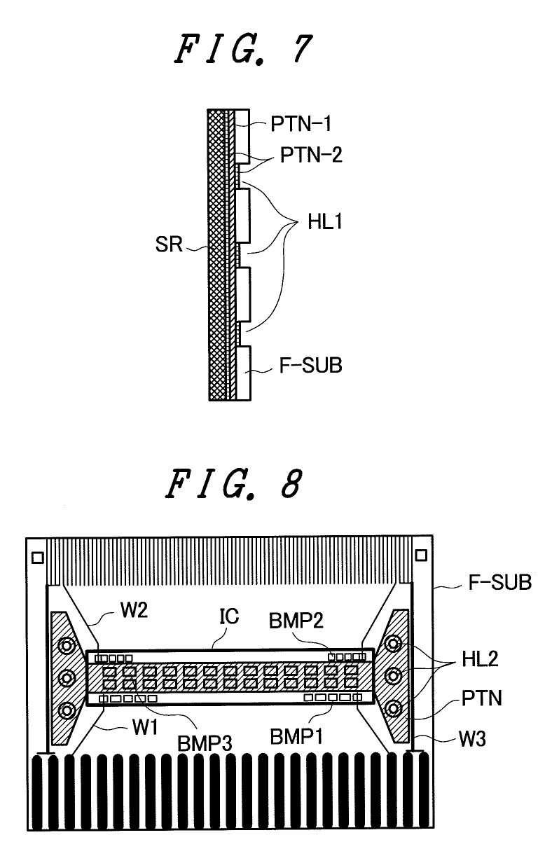

FIG. 7 is a cross-sectional view of the drain driver of the embodiment shown in FIG. 6. The heat radiation pattern formed on the flexible board is constituted of a metal layer (PTN-1) formed of copper foil or the like and a plating layer (PTN-2) formed between a solder resist (SR) and the metal layer. Further, in the flexible board on which the heat radiation patterns are formed, the openings (HL1) shown in FIG. 6 are formed. In this embodiment, also on portions of a surface of the metal layer (PTN-1) at portions of the flexible board where the openings are formed, the plating layer (PTN-2) is formed. Due to such a constitution, it is possible to prevent the metal layer from being directly exposed to the outside. Since a portion of the heat radiation pattern is not covered with the flexible board, the heat radiation effect is further enhanced.

FIG. 8 is a modification of the embodiment shown in FIG. 6 and FIG. 7. In a drain driver shown in FIG. 8, openings (HL2) are formed not only in the flexible board but also in the solder resist (SR). Due to such a constitution, the soldering property is enhanced and hence, the connection of the drain driver to a printed circuit board or the like is facilitated. In this embodiment, further, the openings (HL2) are also formed in the heat radiation pattern. Accordingly, the heat radiation effect can be further enhanced.

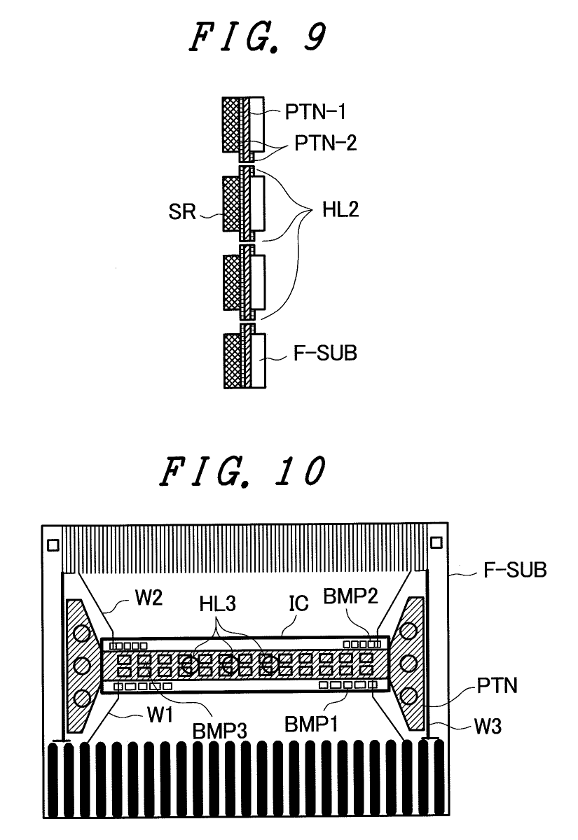

FIG. 9 is a cross-sectional view of the drain driver of the embodiment shown in FIG. 8. In this embodiment, as described previously, the openings (HL2) are formed not only in the flexible board but also in the solder resist (SR). Further, the openings (HL2) are formed in the heat radiation pattern constituted of a metal layer (PTN-1) which forms a plating layer (PTN-2) on both surfaces thereof. Accordingly, the heat radiation effect can be further enhanced. Here, in this embodiment, the openings formed in the heat radiation pattern are made smaller than the openings formed in the flexible board or the openings (HL2) formed in the solder resist. However, the sizes of the openings are not limited particularly. Further, the openings may not be formed in the heat radiation pattern.

FIG. 10 is a modification of the embodiment shown in FIG. 6 and FIG. 7. In the drain driver shown in FIG. 10, openings (HL3) are also formed in a portion of the flexible board where the semiconductor chip is formed. By forming the openings below the semiconductor chip which constitutes a heat source, it is possible to acquire a higher heat radiation effect.

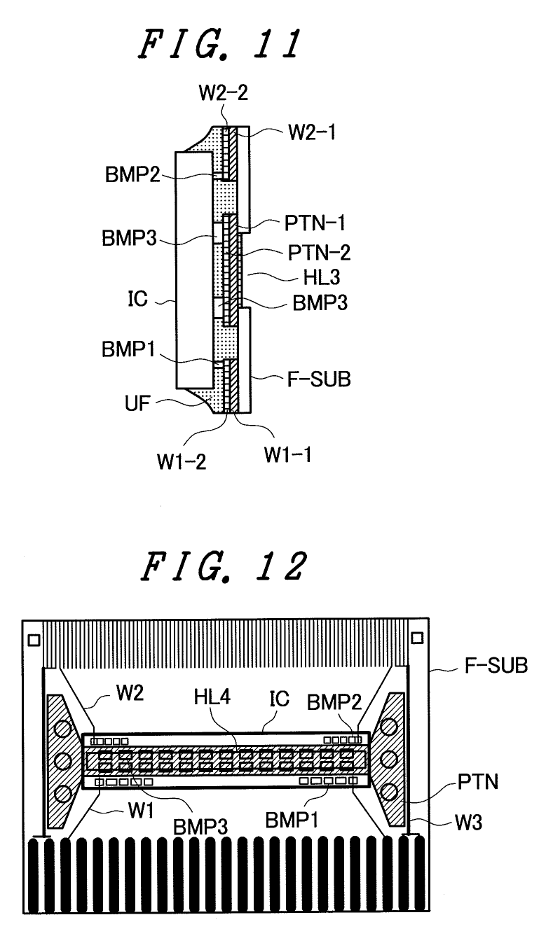

FIG. 11 is a cross-sectional view of the drain driver of the embodiment shown in FIG. 10. In this embodiment, as described previously, the openings (HL3) are formed on portions of the flexible board where the semiconductor chip is formed. On the portions of the flexible board where the openings are formed, a plating layer (PTN-2) is formed on a surface of a metal layer (PTN-1). In this embodiment, the heat radiation bump (BMP3) of the semiconductor chip and the opening overlap each other. However, the openings may not be formed in the portions of the flexible board where the heat radiation bumps are formed.

FIG. 12 is a modification of the embodiment shown in FIG. 6 and FIG. 7. In a drain driver shown in FIG. 12, an opening (HL4) having a rectangular shape is formed in a portion of the flexible board where a semiconductor chip is formed. An area of the opening formed in the flexible board is set larger than an area of the openings formed in the flexible board of the embodiment shown in FIG. 10 and hence, a further heat radiation effect can be expected. Also in this embodiment, the heat radiation bumps (BMP3) of the semiconductor chip and the opening overlap each other. However, the openings may not be formed in portions of the flexible board where the heat radiation bumps are formed.

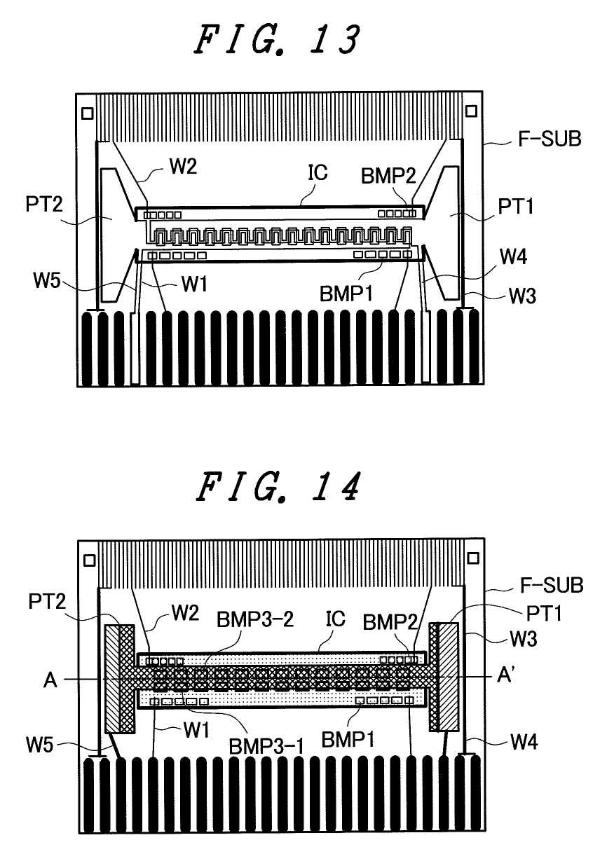

In an embodiment shown in FIG. 13, a first heat radiation pattern (PT1) and a second heat radiation pattern (PT2) which are made of metal are formed on the flexible board. The first heat radiation pattern formed on the flexible board is integrally formed with a fourth line (W4) which is provided for electrically connecting the first heat radiation pattern and a terminal of the printed circuit board, and the second heat radiation pattern is integrally formed with a fifth line (W5) which is provided for electrically connecting the second heat radiation pattern and a terminal of the printed circuit board. In this embodiment, the first heat radiation pattern and the second heat radiation pattern are configured not to be electrically connected with each other on the flexible board. A first voltage is supplied to the first heat radiation pattern from the printed circuit board via the fourth line, and a second voltage is supplied to the second heat radiation pattern from the printed circuit board via the fifth line. Although not particularly limited, for example, a power source voltage may be used as the first voltage, and a GND (ground) voltage may be used as the second voltage. Further, the first heat radiation pattern projects rightwardly in the drawing and the second heat radiation pattern projects leftwardly in the drawing. Due to such a constitution, it is possible to efficiently dissipate heat generated by the semiconductor chip using two heat radiation patterns in the same manner as the above-mentioned embodiment. Further, two heat radiation patterns are respectively formed in a comb-teeth shape and comb-teeth-shaped portions of the respective heat radiation patterns are alternately arranged with each other and hence, it is possible to form a capacitance between two heat radiation patterns. That is, in accordance with the constitution of the above-mentioned two heat radiation patterns, it is possible to form the capacitance between the power source and the GND. Further, for suppressing the lowering of a potential in the inside of the semiconductor chip, a plurality of power source bumps which supplies a power source voltage to the semiconductor chip or a plurality of GND bumps which supplies GND voltage to the semiconductor chip may be formed on the semiconductor chip in a dispersed manner. In this case, by connecting the power source bumps or the GND bumps to two heat radiation patterns of this embodiment, it is possible to supply a voltage from the printed circuit board to the semiconductor chip with low impedance. Conventionally, when the plurality of power source bumps or the plurality of GND bumps is formed on the semiconductor chip, it is necessary to arrange lines formed on the flexible board for supplying a voltage from the printed circuit board to the respective bumps in a dispersed manner or it is necessary to pull around the lines on the flexible board in a complicated manner. However, such line arrangement becomes unnecessary in this embodiment and hence, the lines formed on the flexible board can be simplified and, at the same time, the number of terminals formed on the flexible board can be also decreased. Further, the voltage supply pattern formed on the printed circuit board can be easily pulled around. Here, in the above-mentioned constitution, the line arrangement is explained with respect to the power source bumps or the GND bumps. However, the line arrangement may be applied to first bumps which supply a first voltage and second bumps which supply a second voltage. The same also goes for embodiments explained herein after.

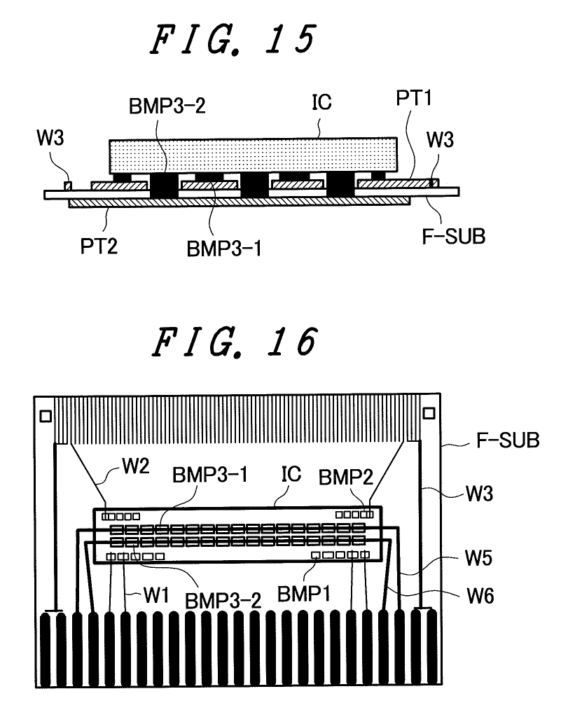

FIG. 14 shows a modification of the embodiment shown in FIG. 13. Also in this embodiment, the first heat radiation pattern (PT1) and the second heat radiation pattern (PT2) made of metal are formed on the flexible board. However, the difference between the modification shown in FIG. 14 and the embodiment shown in FIG. 13 lies in that the first heat radiation pattern is formed on a semiconductor-chip side of the flexible board, and the second heat radiation pattern is formed on a side of the flexible board opposite to the semiconductor chip. The detailed constitution of the modification is explained in conjunction with FIG. 15 described later. In the same manner as the previously-mentioned embodiment, the first heat radiation pattern is integrally formed with the fourth line (W4) provided for electrically connecting the first heat radiation pattern and the terminals of the printed circuit board. However, the second heat radiation pattern is electrically connected to the fifth line (W5) for electrically connecting the second heat radiation pattern to the terminals of the printed circuit board through an opening formed in the flexible board. This opening portion is not shown in the drawing. On the flexible board, the first heat radiation pattern and the second heat radiation pattern are configured not to be connected with each other. Although not particularly limited, a power source voltage is supplied as a first voltage and a GND (ground) voltage is supplied as a second voltage. A plurality of power-source bumps (BMP3-1) and a plurality of GND bumps (BMP3-2) which supply a GND voltage are formed on the semiconductor chip, and the power-source bumps are connected to the first heat radiation pattern. Further, the GND bumps are connected to the second heat radiation pattern through the opening formed in the flexible board. In this constitution, although it is necessary to form the second heat radiation pattern on a back surface of the flexible board, it is possible to dissipate the heat generated by the semiconductor chip using the first heat radiation pattern and the second heat radiation pattern, that is, using the heat radiation patterns formed on both surfaces of the flexible board respectively thus enhancing the heat radiation effect. Further, in this embodiment, a width of the heat radiation pattern arranged below the semiconductor chip can be set larger than a width of the heat radiation pattern of the previously-mentioned embodiment and hence, it is possible to supply a voltage to the semiconductor chip with the low impedance thus forming a larger capacitance component. Due to such a constitution, a bypass capacitor which constitutes a peripheral part becomes unnecessary thus reducing a manufacturing cost of parts.

FIG. 15 is a cross-sectional view of the above-mentioned embodiment taken along a line A-A′ in FIG. 14. In the drawing, the first heat radiation pattern and the second heat radiation pattern are arranged with the flexible board sandwiched there between. The power source bumps which are formed on the semiconductor chip are connected to the first heat radiation pattern, and the GND bumps are connected to the second heat radiation pattern through an opening formed in the flexible board. In this embodiment, the GND bumps are connected to the second heat radiation pattern formed on a back surface of the flexible board and hence, a height of the GND bumps is set higher than a height of the power source bumps. However, the drain driver is not limited to the above-mentioned constitution. That is, the drain driver may be configured such that the opening formed in the flexible board is preliminarily filled with other metal. Further, it is unnecessary to provide the power source bumps and the GND bumps alternately, and the power source bumps may be arranged on one of the opposing long sides of the semiconductor chip and the GND bump may be arranged on another long side of the semiconductor chip.

In an embodiment shown in FIG. 16, a plurality of power-source bumps (BMP3-1) and a plurality of GND (BMP3-2) bumps for supplying a GND voltage are formed on a semiconductor chip, and a fifth line (W5) and a sixth line (W6) are provided for connecting these power-source bumps (BMP3-1) and the GND bumps (BMP3-2) in common respectively. That is, as mentioned previously, on the semiconductor chips, the plurality of power-source bumps or the plurality of GND bumps may be provided for stably supplying a power source voltage or the GND voltage. In this embodiment, by connecting these bumps in common using the fifth line or the sixth line, it is possible to realize the low impedance. Here, plurality of power-source bumps (BMP3-1) and the plurality of GND bumps (BMP3-2) for supplying the GND voltage are formed larger than output bumps (BMP2) and input bumps (BMP1). Due to such a constitution, heat generated by the semiconductor chip can be dissipated efficiently.

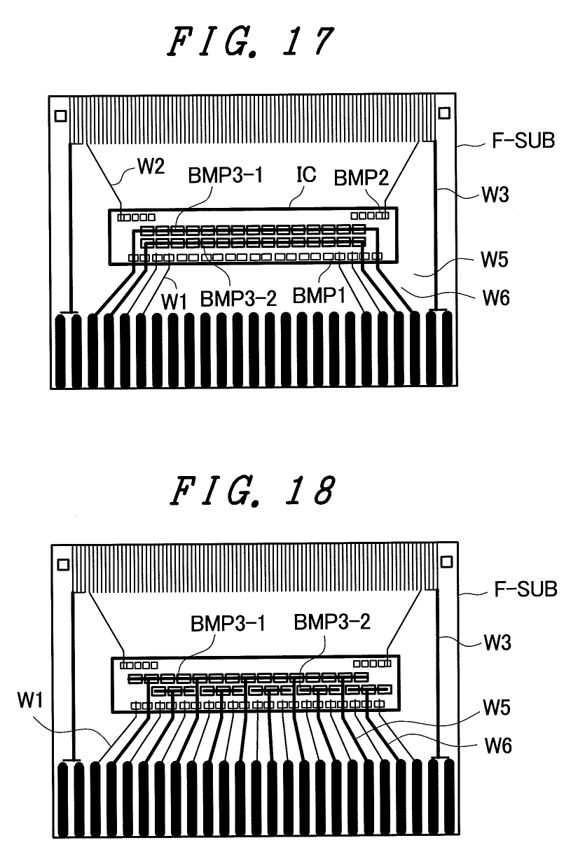

FIG. 17 is a modification of the embodiment shown in FIG. 16. In this embodiment, the fifth line (W5) and the sixth line (W6) are also connected to input bumps (BMP1). The input bumps which are connected to these lines are bumps for inputting the power source voltage or the GND voltage. Further, the fifth line, the sixth line and the first lines which are connected to the input bumps are formed on one long side of the semiconductor chip and hence, it is possible to arrange output bumps on three sides of the semiconductor chip.

In an embodiment shown in FIG. 18, a power source voltage and a GND voltage are supplied to a plurality of power-source bumps (BMP3-1) and a plurality of GND bumps (BMP3-2) for supplying a GND voltage using a plurality of fifth lines and a plurality of sixth lines. Due to such a constitution, it is possible to further lower the impedance. In this embodiment, although one fifth line and one sixth line are respectively connected to three power source bumps and three GND bumps, the number of lines of the fifth lines or the sixth lines to be connected to the power source bumps or the GND bumps is not limited to such a number. However, by adopting the constitution which supplies the voltage to the plurality of bumps using one line, it is possible to arrange the fifth line in a gap defined between the GND bumps and hence, it is possible to form the fifth line and the GND bumps on one plane without making the lines intersect each other. It is needless to say that, to focus on the elimination of the intersecting of the lines, it may be possible to adopt the constitution which supplies the voltage to the plurality of bumps using one line only with respect to the GND bumps, and it may be possible to adopt the constitution which connects all bumps in common with respect to the power source bumps. In this embodiment, although the fifth line and the sixth line are pulled out from the long side of the semiconductor chip, as shown in FIG. 16, these two lines or only the fifth line may be pulled out from a short side.

FIG. 19 shows a modification of the embodiment shown in FIG. 16. In this embodiment, the fifth line and the sixth line are formed in a comb-teeth shape, and these lines are configured to be engaged with each other in a plan view on a flexible board. Due to such a constitution, it is possible to form a capacitance between a power source and a GND on the flexible board and hence, the number of parts can be reduced as mentioned previously. By adopting such a constitution, it is possible to further enhance a heat radiation effect. Here, the combination of the comb-teeth portions which forms the capacitance is arranged between the semiconductor chip and the third line on the flexible board and at a portion of the flexible board where other lines are not formed. However, the arrangement of the combination of the comb-teeth portions is not limited to such an arrangement and the combination of the comb-teeth-portions may overlap the semiconductor chip or may be arranged below the semiconductor chip.

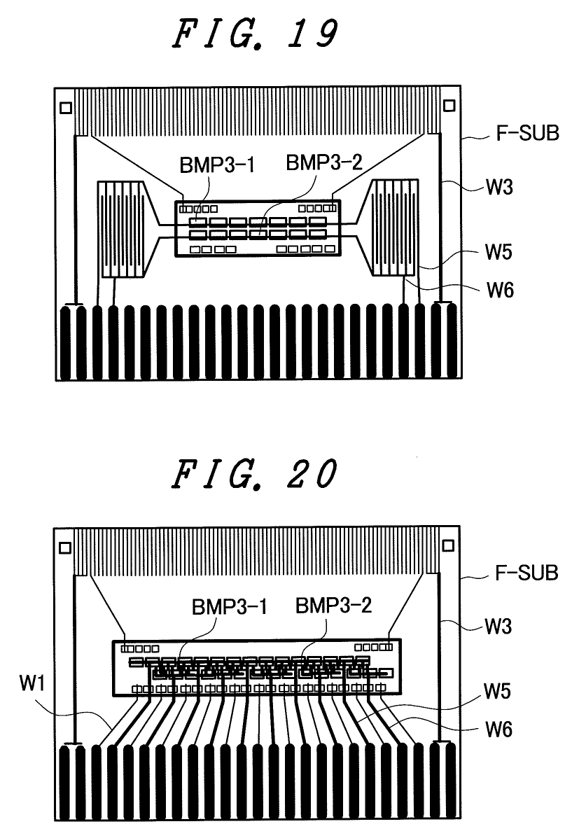

An embodiment shown in FIG. 20 is characterized by adding a capacitance to the embodiment shown in FIG. 18. One fifth line which is connected in common to a plurality of power source bumps formed between a semiconductor chip and a flexible board and one sixth line which is connected in common to a plurality of GND bumps formed between the semiconductor chip and the flexible board respectively have comb teeth, and the capacitance is formed by engaging these comb teeth. It is needless to say that, as mentioned previously, all bumps may be connected in common with respect to the power source bumps.

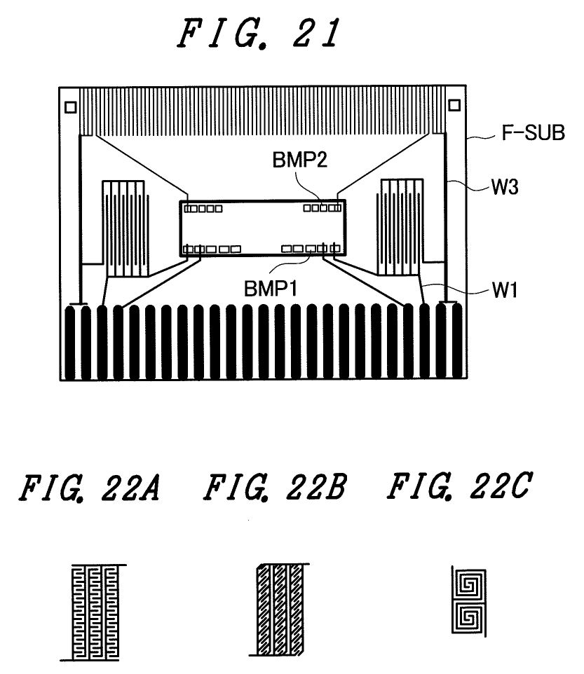

FIG. 21 shows an embodiment which focuses on the formation of a capacitance on a flexible board. In this embodiment, a portion of a third line (W3) which is not connected with a semiconductor chip and a portion of a first line (W1) which is connected to an input bump (BMP1) of the semiconductor chip are formed in a comb-teeth shape, and a capacitance is formed by engaging these comb-teeth portions of the third line (W3) and the first line (W1). As mentioned previously, a portion of the flexible board where the capacitance is formed is not particularly limited. Further, in this embodiment, although the capacitance is formed between the third line and the first line, portions of two first lines may be formed in a comb-teeth shape, and the capacitance may be formed between two first lines.

FIG. 22A to FIG. 22C show another mode of the capacitance which is formed by the lines arranged on the flexible board. In the embodiment shown in FIG. 21, the first line and the third line are formed into a comb-teeth shape, and the capacitance is formed by engaging the comb-teeth portions in a zigzag manner. In FIG. 22A, each tooth of each comb-teeth portion is further formed into a comb-teeth shape, and these comb-teeth portions are alternately arranged with each other. In FIG. 22B, teeth which are formed on each tooth of the comb-teeth portion are formed obliquely. Further, in FIG. 22C, one line is formed in a vortex shape and another line is formed in a vortex shape within a vortex of one line. Here, although two vortices are formed in FIG. 22C, the number of vortices may be one or three or more. Due to such a constitution, the capacitance can be further increased.

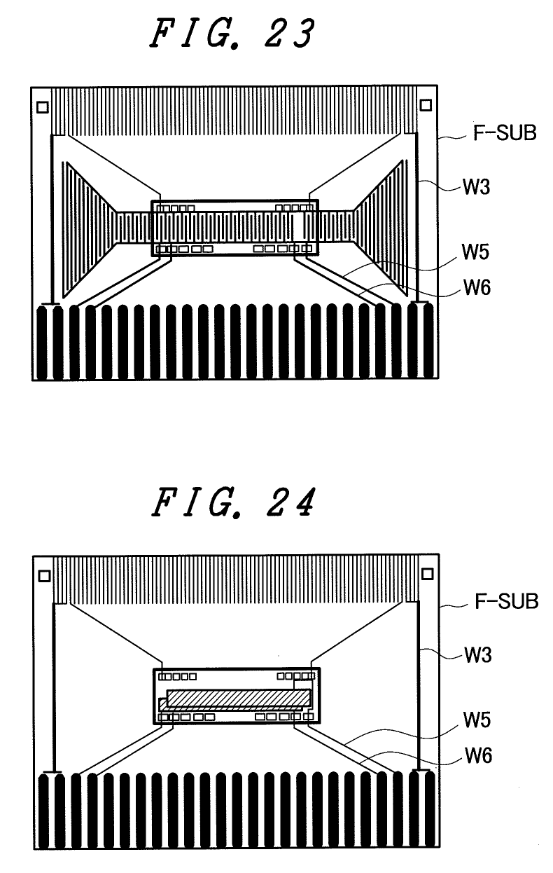

In an embodiment shown in FIG. 23, the above-mentioned capacitance is also formed between a semiconductor chip and a flexible board. Due to such a constitution, it is possible to realize the further higher capacitance. In this embodiment, although heat radiation bumps are not formed on the semiconductor chip, it is possible to dissipate heat generated by the semiconductor chip in a wide range of the flexible board by way of metal lines which form the capacitance and hence, a heat radiation effect can be also expected. It is needless to say that the heat radiation bumps explained previously may be formed on the semiconductor chip and these heat radiation bumps may be connected with lines which form the capacitance. Further, capacitances which are formed on both sides of the semiconductor chip may be simply electrically connected with each other using lines formed between the semiconductor chip and the flexible board without forming the capacitance between the semiconductor chip and the flexible board.

In an embodiment shown in FIG. 24, metal layers which are connected to a third line and a sixth line respectively are provided. These metal layers are arranged between a flexible board and a semiconductor chip in a state that an insulation material is formed between the metal layers. Due to such a constitution, this embodiment can form the capacitance further larger than the previously mentioned capacitance.

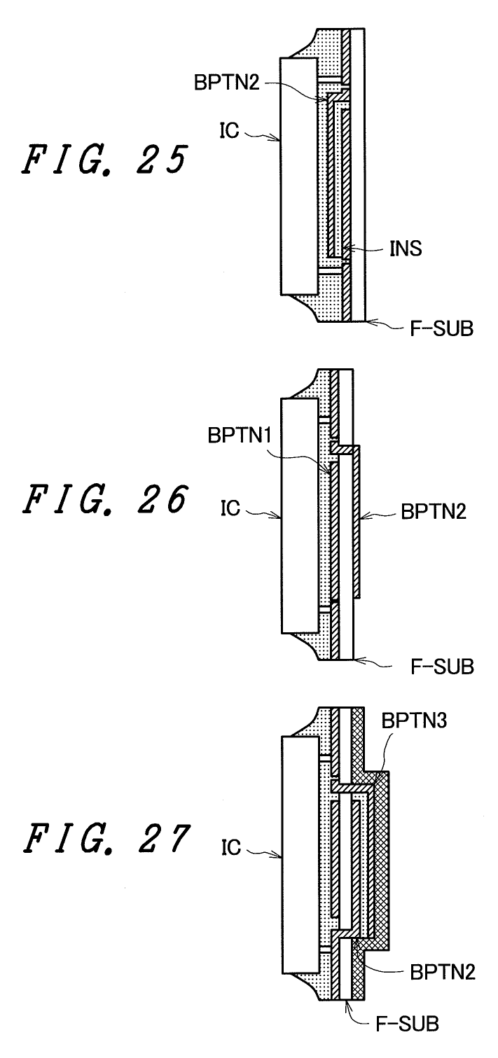

FIG. 25 is a cross-sectional view of the embodiment shown in FIG. 24. The first metal layer (BPTN1) is formed on the same layer as lines formed on the flexible board, and the second metal layer (BPTN2) is formed between the first metal layer and the semiconductor chip by way of the insulation material (INS). Here, the insulation material may be made of the same material as a solder resist or an underfill, or the insulation material may be a material other than the solder resist and the under fill which has one surface or a portion thereof covered with a material which exhibits high relative inductivity.

FIG. 26 is a cross-sectional view of another embodiment corresponding to the embodiment shown in FIG. 24. A second metal layer (BPTN2) which forms a capacitance between the second metal layer (BPTN2) and a first metal layer formed on the same layer as lines formed on a flexible board is formed on a back surface of the flexible board. A surface of the second metal layer formed on the back surface of the flexible board is covered with a solder resist. Due to such a constitution, two metal layers use the flexible board as a dielectric and hence, it is no more necessary to form another metal layer on the surface of the flexible board as in the case of the embodiment shown in FIG. 25.

FIG. 27 is a cross-sectional view of another embodiment corresponding to the embodiment shown in FIG. 24. In this embodiment, both of two metal layers (BPTN2, BPTN3) which form a capacitance are formed on a back surface of a flexible board. An insulation layer formed between two metal layers may be made of the same material as a solder resist or underfill, or the insulation layer may be configured by applying a material other than a solder resist and underfill and having high relative inductivity to one surface or a portion thereof. Further, the capacitance formed by two metal layers is covered with the solder resist. Due to such a constitution, it is possible to form heat radiation bumps explained in conjunction with the above-mentioned embodiment on the semiconductor chip thus forming a heat radiation pattern between the flexible board and the semiconductor chip. Further, in this embodiment, it is unnecessary to provide the capacitance formed by two metal layers only to a portion of the flexible board where the semiconductor chip is mounted and hence, the capacitance can be formed using a metal layer having an area larger than a surface area of the semiconductor chip. Further, it is also possible to form the capacitance using metal layers having the substantially same size as the flexible board. It is needless to say that, also in the previously-mentioned embodiments, the capacitance may be formed using the metal layers having the larger area than the semiconductor chip.

In the above-mentioned embodiments, the explanation has been made with respect to the drain driver. However, the present invention is also applicable to the gate driver. Further, the present invention is not limited to the drain driver and the gate driver, and is applicable to a flexible board in general which is connected to a substrate made of glass or the like of a display device and mounts a semiconductor chip thereon. Further, in the above-mentioned embodiments, the explanation has been made with respect to the constitution of the drain driver which connects one side thereof to the glass substrate and another side thereof to the printed circuit board. However, the drain driver may be configured such that the drain driver is not connected to the printed circuit board and input signals to the semiconductor chip may be supplied from the glass substrate. In this case, third lines which are formed on both sides of the flexible board may be connected with each other and these lines and terminals of the semiconductor chip may be electrically connected with each other. The present invention is not limited to the constitutions shown in this specification and attached drawings and the constitution of the present invention may be suitably changed without departing from a technical concept of the present invention.

What is claimed is:

1. A display device comprising:
an insulation substrate;
a flexible board which is connected to the insulation substrate; and
a semiconductor chip which is mounted on the flexible board, wherein
the semiconductor chip includes a first long side and a second long side,
first bumps are formed on the semiconductor chip along the first long side and second bumps are formed on the semiconductor chip along the second long side,
the first bumps and the second bumps are connected to a plurality of lines formed on the flexible board, and
a pattern formed of a metal layer formed on the same layer as the plurality of lines is formed on the flexible board between the first bumps and the second bumps.

2. A display device according to claim 1, wherein the pattern has a width larger than respective widths of the plurality of lines.

3. A display device according to claim 1, wherein the pattern is formed on the flexible board in a state that the pattern extends from a portion of the flexible board where the semiconductor chip is mounted to a portion of the flexible board where the semiconductor chip is not mounted, and the pattern is formed between the flexible board and a protective film in the portion of the flexible board where the semiconductor chip is not mounted.

4. A display device according to claim 1, wherein the semiconductor chip includes a first short side and a second short side which are arranged orthogonal to the first long side, and the pattern is formed in a state that the pattern extends from a portion of the flexible board where the semiconductor chip is mounted to a portion of the flexible board where the semiconductor chip is not mounted between the first short side and the flexible board.

5. A display device according to claim 1, wherein third bumps are formed on the semiconductor chip between the first bumps and the second bumps, and the pattern and the third bumps are connected with each other.

6. A display device according to claim 5, wherein a plurality of third bumps is formed in parallel to the first long side.

7. A display device according to claim 5, wherein an area of the third bump is set larger than an area of the first bump and an area of the second bump.

8. A display device according to claim 1, wherein an opening is formed in a portion of a region of the flexible board where the pattern is formed.

9. A display device according to claim 8, wherein the opening formed in the flexible board includes an opening formed in a portion of the pattern.

10. A display device according to claim 7, wherein the opening formed in the flexible board is formed in a portion of the flexible board where the semiconductor chip is mounted.

11. A display device according to claim 8, wherein the opening formed in the flexible board is formed in a portion of the flexible board where the semiconductor chip is not mounted.

12. A display device according to claim 1, wherein the pattern includes a first pattern and a second pattern, and a capacitance is formed between the first pattern and the second pattern.

13. A display device according to claim 12, wherein the first pattern is formed between the flexible board and the semiconductor chip, the second pattern is formed between the first pattern and the semiconductor chip, and an insulation layer is formed between the first pattern and the second pattern.

14. A display device according to claim 5, wherein a back-surface pattern is formed on a surface of the flexible board opposite to a surface of the flexible board where the semiconductor chip is mounted,
the pattern is connected to some third bumps, and
the back-surface pattern is connected with some other third bumps which differ from some third bumps.

15. A display device comprising:
an insulation substrate;
a flexible board which is connected to the insulation substrate; and
a semiconductor chip which is mounted on the flexible board, wherein
the semiconductor chip includes a first long side and a second long side,
first bumps are formed on the semiconductor chip along the first long side and second bumps are formed on the semiconductor chip along the second long side,
a plurality of third bumps and a plurality of fourth bumps are formed between the first bumps and the second bumps, and
a first pattern which is connected in common to the plurality of third bumps and a second pattern which is connected in common to the plurality of fourth bumps are formed on the flexible board.

16. A display device according to claim 15, wherein the first pattern and the second pattern form a capacitance between the semiconductor chip and the flexible board.

17. A display device according to claim 15, wherein the first pattern is formed between the semiconductor chip and the flexible board, and the second pattern is formed between the first pattern and the semiconductor chip.

18. A display device according to claim 15, wherein the first pattern and the second pattern form a capacitance on a portion of the flexible board where the semiconductor chip is not mounted.

19. A display device according to claim 18, wherein the first pattern and the second pattern are formed in comb-teeth shape, and comb-teeth portions of the respective patterns are alternately formed.

20. A display device according to claim 15, wherein a first voltage supplied to the semiconductor chip is supplied to the first pattern, and a second voltage is supplied to the semiconductor chip is applied to the second pattern.
